(19) United States
(12) Patent Application Publication
(10) Pub. No.: US 2015/0015118 A1
(43) Pub. Date: Jan. 15, 2015

(54) PIEZOELECTRIC DEVICE AND METHOD FOR FABRICATING THE SAME

(71) Applicant: NIHON DEMPA KOGYO CO., LTD., TOKYO (JP)

(72) Inventor: ATSUSHI KAMIJO, SAITAMA (JP)

(21) Appl. No.: 14/324,095

(22) Filed: Jul. 4, 2014

(30) Foreign Application Priority Data
Jul. 9, 2013 (JP) 2013-143496

(51) Int. Cl. H01L 41/053; H01L 41/23

(52) U.S. Cl. CPC H01L 41/053; H01L 41/23
USPC 310/344; 29/25.35

(57) ABSTRACT

A piezoelectric device includes a piezoelectric vibrating piece, a base, a first lid, and a second lid. The piezoelectric vibrating piece includes an electrode. The base holds the piezoelectric vibrating piece. The first lid is bonded to the base. The first lid houses the piezoelectric vibrating piece in a cavity. The first lid has an opening portion that opens the cavity. The second lid is bonded to a front surface of the first lid so as to cover the opening portion. The opening portion is fabricated at a position overlapping a portion including a region of the piezoelectric vibrating piece excluding the electrode, or a portion including a region excluding the piezoelectric vibrating piece in plan view.

### CROSS-REFERENCE TO RELATED APPLICATIONS

This application claims the priority benefit of Japan application serial no. 2013-143496, filed on Jul. 9, 2013. The entirety of the above-mentioned patent application is hereby incorporated by reference herein and made a part of this specification.

### TECHNICAL FIELD

This disclosure relates to a piezoelectric device and a method for fabricating the piezoelectric device.

### DESCRIPTION OF THE RELATED ART

A piezoelectric resonator (piezoelectric device) such as a crystal unit is fabricated by placing a quartz crystal piece (piezoelectric vibrating piece) in a package made of a ceramic or similar material, then hermetically sealing or vacuum-sealing the package. However, growing market demands for reduction in size, profile, and price of electronic components make it difficult to use a ceramic package. In order to meet these demands, piezoelectric resonators using a glass package have been proposed (for example, see Japanese Unexamined Patent Application Publication Nos. 2004-6525 and 2012-74649).

Example structures of a glass package include a structure in which a quartz crystal piece is placed in a depressed portion formed on either one of a lid or a base, which are bonded to each other, or a structure in which a lid and a base are respectively bonded to a front surface and a back surface of a quartz crystal piece having a framing portion (for example, see Japanese Unexamined Patent Application Publication No. 2000-68780). Both structures can be fabricated in wafer level, which allows reduction in size, profile, as well as cost, compared with a conventional ceramic package.

In the fabrication of the glass packages having the above-described structures, examples of proposed bonding methods for bonding a glass wafer to a glass wafer, or a glass wafer to a crystal wafer, include: direct wafer bonding method, anodic bonding method, thermo-compression metal bonding method, glass frit bonding method, plasma activation bonding method, and ion-beam activation bonding method. The direct wafer bonding method requires high temperature heat treatment for obtaining sufficient bonding strength, which is problematic for a bonding method of a crystal unit. The anodic bonding method is a bonding method for bonding a glass wafer containing alkali ions, and generates gases during bonding, which deteriorates degree of vacuum in a package.

The thermo-compression metal bonding method is bonding method for bonding via a metal such as AuSn eutectic metal, and thus requires the formation of an adhesive layer or a barrier layer, and patterning them, which disadvantageously increases fabrication cost. The glass frit bonding method generates gases from a low melting point glass paste during bonding, which deteriorates degree of vacuum in a package. The plasma activation bonding method is considered to be difficult for bonding in vacuum. The ion-beam activation bonding method involves irradiating an argon beam or a similar beam to wafers to remove contamination on the surfaces of the wafers, and bringing both surfaces into contact with each other, which allows bonding a variety of materials at room temperature (for example, see Japanese Unexamined Patent Application Publication No. 2008-178071).

The ion-beam activation bonding method involves two process, including: an activation process by irradiating an ion beam, and a bonding process for bonding wafers, and these processes are generally performed in the same chamber. Accordingly, stopping argon supply immediately after the activation process and evacuating the chamber allows the wafers to be bonded while achieving a pressure requirement for a crystal unit. Note that, since a member of an ion source main body and an inner wall of a chamber are simultaneously sputtered during irradiation of ion beam, iron (Fe), chrome (Cr), and aluminum (Al), which are constituent materials (stainless steel or aluminum alloy) of those members, are fabricated on the surfaces of the wafers (for example, Japanese Unexamined Patent Application Publication No. 2007-324195). Thus, in the ion-beam activation bonding method, since the etching caused by the sputtering action on the surface of wafers, and a deposition of iron, chrome, and aluminum are simultaneously occurred with irradiation of ion beam, which achieves a strong bonding between glass or crystal wafers.

As described above, the ion-beam activation bonding method may be the most appropriate as a method of bonding a glass package in wafer level, since it can achieve a degree of vacuum required for a piezoelectric device at room temperature.

In a type of a glass package composed of a lid and a base, a various kinds of interconnections such as through-holes interconnection and connection electrodes are fabricated on, for example, the surface of the base. Also, on a quartz-crystal vibrating piece, which is placed on the base, an excitation electrode and an extraction electrode are fabricated, and this extraction electrode is electrically connected to the connection electrodes on the base. Also, in a type of a glass package, whose lid and base are respectively bonded to a front surface and a back surface of a quartz-crystal vibrating piece having a frame portion, a various kind of electrodes are formed on the base, and similarly excitation electrodes and extraction electrodes are also formed on the quartz-crystal vibrating piece.

In anyone of the above types, when the ion-beam activation bonding method is used for bonding the lid, the electrodes fabricated on the quartz-crystal vibrating piece and the base are exposed to irradiation of ion beam, and causes etching by sputtering action of argon and deposition of metal elements that constitute the inner wall of the chamber. The etching amounts of the electrodes of the quartz-crystal vibrating pieces and the deposition amounts of the metal element vary depending on the mounting position of the quartz-crystal vibrating piece or the forming positions of the quartz-crystal vibrating pieces within the wafer. The distribution of the etching and the deposition is equivalent to a distribution of the resonance frequency variation of the quartz-crystal vibrating pieces in a wafer surface. The frequency variation shifts toward a positive side in a region where etching amounts of the electrodes are larger than deposition amounts of the metal elements. In contrast the frequency variation shifts toward a negative side in a region where etching amounts of the electrodes are smaller than deposition amounts of the metal elements. In the fabrication of a crystal unit, such a frequency variation caused after bonding of the wafers unfortunately decreases product yield.

In addition, Japanese Unexamined Patent Application Publication No. 2008-178071 discloses a method for coating an excitation electrode with an electrode cover before plasma beam or ion beam is irradiated when the plasma activation bonding method or the ion-beam activation bonding method are used. It is, however, cumbersome to coat the excitation electrode of each piezoelectric vibrating piece with the electrode in wafer level, and increases production cost. In addition, since the electrode cover is also etched by an ion beam or a similar beam, the deposition of the metal elements may affect the vibration characteristic of the piezoelectric vibrating piece.

A need thus exists for a piezoelectric device and a method for fabricating a piezoelectric device which is not susceptible to the drawbacks mentioned above.

### SUMMARY

A piezoelectric device according to the disclosure includes a piezoelectric vibrating piece, a base, a first lid, and a second lid. The piezoelectric vibrating piece includes an electrode. The base holds the piezoelectric vibrating piece. The first lid is bonded to the base. The first lid houses the piezoelectric vibrating piece in a cavity. The first lid has an opening portion that opens the cavity. The second lid is bonded to a front surface of the first lid so as to cover the opening portion. The opening portion is disposed at a position overlapping a portion including a region of the piezoelectric vibrating piece excluding the electrode, or a portion including a region excluding the piezoelectric vibrating piece, in plan view.

### BRIEF DESCRIPTION OF THE DRAWINGS

The foregoing and additional features and characteristics of this disclosure will become more apparent from the following detailed description considered with reference to the accompanying drawings.

FIG. 1A is a developed perspective view illustrating a piezoelectric device according to a first embodiment.

FIG. 1B is a cross-sectional view taken along the line IB-IB of FIG. 1A.

FIG. 2A is a plan view illustrating one example of an opening portion.

FIG. 2B is a plan view illustrating another example of an opening portion.

FIG. 3 illustrates one example of a fabrication process of the piezoelectric vibrating piece illustrated in FIGS. 1A and 1B.

FIG. 4 is a schematic view illustrating an ion beam activation bonding apparatus.

FIG. 5 is a cross-sectional view illustrating a piezoelectric device according to a second embodiment.

FIG. 6A is a developed perspective view illustrating a piezoelectric device according to a third embodiment.

FIG. 6B is a cross-sectional view taken along the line VIB-VIB of FIG. 6A.

FIG. 7 illustrates a fabrication process of the piezoelectric device illustrated in FIGS. 6A and 6B.

### DETAILED DESCRIPTION

The following description describes the embodiments of this disclosure with reference to the drawings. Note that, this disclosure is not limited to these embodiments. In addition, the drawings are appropriately scaled, for example, partially enlarged or highlighted to describe the embodiments. The following description describes the directions in each drawing below using the XYZ coordinate system. In the XYZ coordinate system, the XZ plane corresponds to a plane parallel to a front surface of a piezoelectric vibrating piece. In the XZ plane, the X direction corresponds to the longitudinal direction of the piezoelectric vibrating piece, and the Z direction corresponds to the direction perpendicular to the X direction. The Y direction corresponds to the direction perpendicular to the XZ plane (thickness direction of piezoelectric vibrating piece). The explanations are given assuming that the positive direction corresponds to a direction that is indicated by the arrow, and the negative direction corresponds to a direction opposite to the positive direction in each of the X direction, the Y direction, and the Z direction.

### Configuration of Piezoelectric Device 100 According to First Embodiment

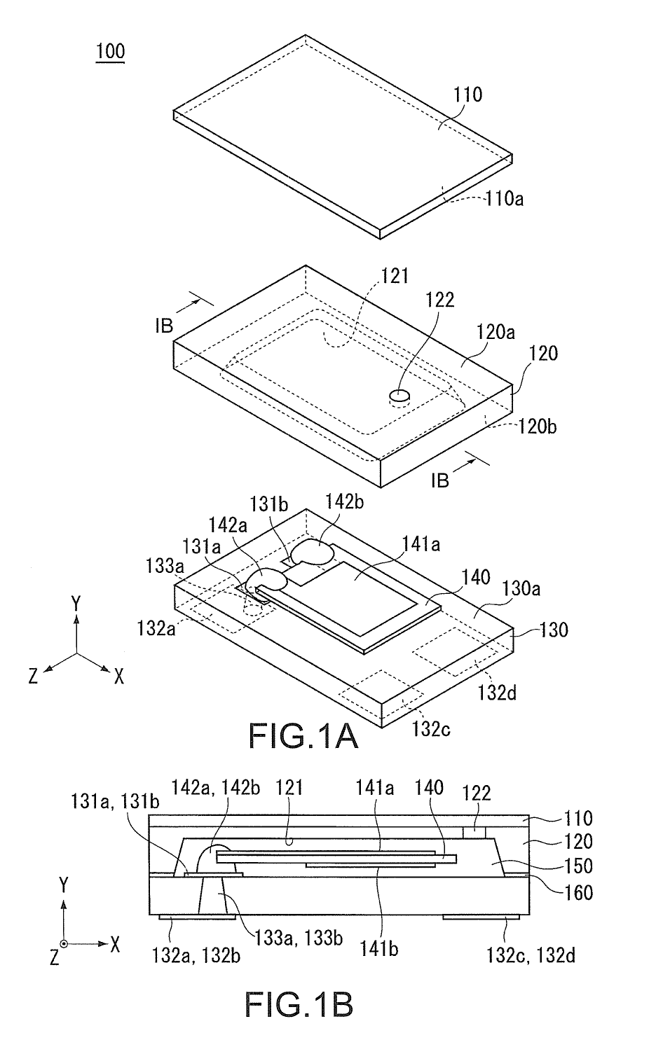

The following description describes a piezoelectric device 100 according to the first embodiment with reference to FIGS. 1A and 1B. As illustrated in FIG. 1A, the piezoelectric device 100 is a piezoelectric resonator that includes a second lid 110, a first lid 120, a base 130 and, a piezoelectric vibrating piece 140. The base 130, on which the piezoelectric vibrating piece 140 is placed, is bonded to the first lid 120, for example, via a seal 160 made of low melting point glass, further the first lid 120 is bonded to the second lid 110 by the ion-beam activation bonding method.

The second lid 110, the first lid 120, and the base 130 are made of borosilicate glass. This, however, should not be construed in a limiting sense. Examples of the materials of the second lid 110, the first lid 120 and the base 130 include all glasses that include ceramic materials made of inorganic oxides, such as soda-lime glass, non-alkali glass and quartz. Also, common ceramics such as low temperature co-fired ceramic (LTCC) or alumina may be used as long as they have a surface smoothness required for bonding. Although the glass materials used for the second lid 110, the first lid 120, and the base 130 do not necessarily need to be made of the same kind of material, use of the same kind of glass material results in a constant thermal expansion coefficient, which allows inhibiting a stress generated by temperature change. In addition, alkali glass may be used when the first lid 120 is bonded to the base 130 by the anodic bonding method.

The second lid 110 is a plate-shaped member having a rectangular shape. The second lid 110 includes a bonding surface 110a, which is bonded to the first lid 120, having a sufficient smoothness appropriate for being bonded by the ion-beam activation bonding method (typically, average roughness Ra is around 1 nm).

The first lid 120 is a plate-shaped member having a rectangular shape in plan view, and includes a depressed portion 121 on the back surface (−Y-side surface) as illustrated in FIG. 1A. Then, an opening portion 122 is disposed at a portion of the depressed portion 121, and the opening portion 122 passes through the first lid 120 in the Y direction. The first lid 120 includes a bonding surface 120a, which is bonded to the second lid 110, having a sufficient smoothness appropriate for being bonded by the ion-beam activation bonding method (typically, the average roughness Ra is around 1 nm). On the other hand, a bonding surface 120b of the first lid 120 surrounding the depressed portion 121, which is bonded to the base 130, is not required to have a smoothness required for being bonded by the ion-beam activation bonding method. However, it may have a similar smoothness.

The opening portion 122 serves as a through-hole for drawing a vacuum in a space (cavity) 150 around the piezoelectric vibrating piece 140, when the second lid 110 is bonded to the first lid 120 after the first lid 120 is bonded to the base 130. Also, the opening portion 122 is fabricated at a position that can reduce the influence to the piezoelectric vibrating piece 140 by ion beams when the second lid 110 is bonded to the first lid 120.

The base 130 is a plate-shaped member having a rectangular shape. As illustrated in FIG. 1B, bonding the bonding surface 120b of the first lid 120 to a front surface 130a (+Y-side surface) of the base 130 forms a cavity 150, which houses the piezoelectric vibrating piece 140. Note that, a portion of the front surface 130a, which portion is bonded to the bonding surface 120b of the first lid 120, has a smoothness similar to that of the bonding surface 120b of the first lid 120 among the bonding surfaces.

At the −X-side of the front surface 130a of the base 130, connecting electrodes 131a and 131b having a rectangular shape are aligned in the Z direction. At the four corners on the back surface (−Y-side surface) of the base 130, external electrodes 132a, 132b, 132c, and 132d having rectangular shapes are respectively formed. Note that, the external electrode 132b at the −X-side and the −Z-side is not illustrated in FIG. 1A, since it is hidden behind the piezoelectric vibrating piece 140. The external electrodes 132a and 132b are used as a pair of mounting terminals when the piezoelectric device 100 is implemented on a substrate. The external electrodes 132c and 132d are dummy electrodes, which are not electrically connected to other electrodes.

A through-hole interconnection 133a (or 133b), which passes through the base 130 in the Y direction, is fabricated between the connecting electrode 131a (or 131b) and the external electrode 132a (or 132b). The through-hole interconnection 133a (or 133b) electrically connects the connecting electrode 131a (or 131b) and the external electrode 132a (or 132b).

The connecting electrodes 131a and 131b and the external electrodes 132a, 132b, 132c, and 132d are conductive metal films. The metal films have a layered structure including, for example, chrome (Cr), titanium (Ti), nickel (Ni), nickel-chrome (NiCr) alloy, nickel-titanium (NiTi) alloy, or nickel-tungsten (NiW) alloy as a base layer, on which gold (Au), nickel (Ni), or copper (Cu) is plated. Alternatively, the metal films are formed by printing a conductive paste including powder particles of silver or copper and firing it. The through-hole interconnection 133a (or 133b) is formed by filling a through-hole fabricated on the base 130 by copper plating. Alternatively, the through-hole interconnection 133a (or 133b) is formed by filling the through-hole fabricated on the base 130 with a conductive paste including powder particles of silver or copper.

The piezoelectric vibrating piece 140 is, for example, an AT-cut quartz-crystal vibrating piece. The front surface and back surface of the piezoelectric vibrating piece 140 respectively have excitation electrodes 141a and 141b, which are made of gold (Au) or silver (Ag). The excitation electrodes 141a and 141b are respectively electrically connected to the connecting electrodes 131a and 131b via conductive pastes 142a and 142b. Note that, the excitation electrodes 141a and 141b are conductive metal layers including: chrome (Cr), titanium (Ti), nickel (Ni), nickel-chrome (NiCr) alloy, nickel-titanium (NiTi) alloy, or nickel-tungsten (NiW) alloy as a base layer for increasing adhesion with crystal, and a main electrode layer of gold (Au) or silver (Ag) is formed on the base layer.

The piezoelectric vibrating piece 140 is placed on the base 130, and a signal from the external electrode terminal is applied to activate the piezoelectric vibrating piece 140, and a frequency of the piezoelectric vibrating piece 140 is adjusted to obtain the desired resonance frequency. After that, as illustrated in FIG. 1B, the first lid 120 is bonded to the base 130, and the second lid 110 is bonded to the first lid 120, which houses the piezoelectric vibrating piece 140 in the cavity 150. The inside of the cavity 150 is sealed in vacuum or inert gas atmosphere of, for example, nitrogen gas.

The first lid 120 is bonded to the base 130 using a bonding method other than the ion-beam activation bonding method, since the bonding method is required not to shift the resonance frequency of the piezoelectric vibrating piece 140 placed on the base 130. Namely, anyone of the thermo-compression metal bonding method, the glass frit bonding method, the anodic bonding method, or the plasma activation bonding method is used. If the first lid 120 is bonded to the base 130 using the thermo-compression metal bonding method, as illustrated in FIG. 1B, the seal layer 160 is fabricated on each bonding portion of the first lid 120 and the base 130, the seal layer 160 being made of a metal that can be bonded by the thermo-compression metal bonding method, for example, gold, aluminum, or low melting point metal such as AuSn.

On the other hand, if the first lid 120 is bonded to the base 130 using the glass frit bonding method, the seal layer 160, which is made of low melting point glass, is fabricated on each bonding portion of the first lid 120 and the base 130. In addition, if the first lid 120 is bonded to the base 130 using the anodic bonding method, at least one of the first lid 120 and the base 130 should be made of alkali glass, then silicon (Si) is used as the seal layer 160. Note that, regarding the electric potentials during anodic bonding, the alkali glass side should be cathode, while the opposite side should be anode. Also, if the first lid 120 is bonded to the base 130 using the plasma activation bonding method, the seal layer 160 is not required, but only piezoelectric vibrating piece 140 with an electrode of gold (Au) should be used since the bonding surfaces of the first lid 120 and the base 130 are exposed to oxygen plasma.

Bonding between the first lid 120 and the base 130 does not necessarily need to be performed in vacuum, and may be performed in nitrogen atmosphere, or even in atmosphere, as long as the resonance frequency of the piezoelectric vibrating piece 140 is unchanged.

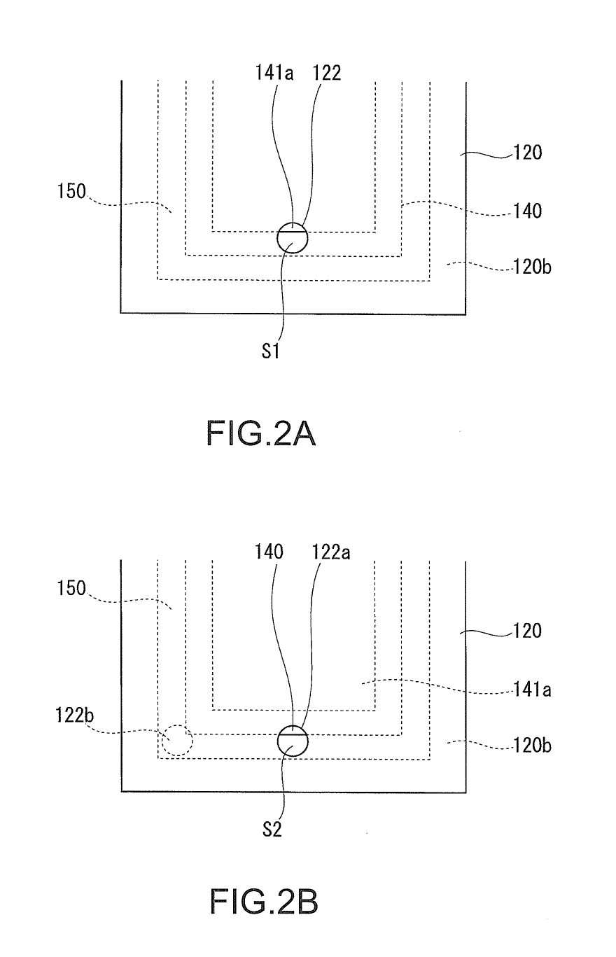

The second lid 110 is bonded to a bonded body of the first lid 120 and the base 130 by the ion-beam activation bonding method. As illustrated in FIG. 2A, the opening portion 122 is fabricated at a position overlapping a portion including a region S1 in plan view, which is a region excluding the excitation electrode 141a on the piezoelectric vibrating piece 140. The opening portion 122 may have any size. Also, the opening portion 122 does not necessarily have a circular shape, and may have any shape such as an elliptical shape, an oval shape, or a polygonal shape. Any number of the opening portions 122 may be fabricated at two or more positions. If two or more opening portions 122 are fabricated, they may have the same shape or different shapes. Note that, although the opening portion 122 in FIG. 2A is fabricated with overlapping a part of the excitation electrode 141a of the piezoelectric vibrating piece 140, the opening portion 122 may be fabricated with only overlapping the region S1.

Thus, the piezoelectric vibrating piece 140 is covered with the first lid 120 excluding the opening portion 122, and the opening portion 122 is fabricated at a position overlapping a portion including the region S1 that is a region excluding the excitation electrode 141a on the piezoelectric vibrating piece 140. Accordingly, a large amount of ion beam is not irradiated to the excitation electrode 141a of the piezoelectric vibrating piece 140 during ion beam activation, and metals, which are sputtered from inside of the apparatus by ion beam irradiation, do not widely deposit on the excitation electrode 141a. Consequently, variation in the resonance frequency of the piezoelectric vibrating piece 140 can be prevented. Meanwhile, a vacuum can be drawn on the cavity 150 formed by bonding the first lid 120 to the base 130 through the opening portion 122 of the first lid 120. Thus, the piezoelectric device 100 having a vacuum hermetically sealed glass package can be fabricated without changing the resonance frequency of the piezoelectric vibrating piece 140 even using the ion-beam activation bonding method.

Also, as illustrated in FIG. 2B, an opening portion 122a may be fabricated at a position overlapping, in plan view, a portion including a region S2, which is a region excluding the piezoelectric vibrating piece 140. In addition, the opening portion 122a may be fabricated along the bonding surface 120b of the first lid 120 (a portion bonded to the base 130). Fabricating the opening portion 122a along the bonding surface 120b allows reducing the size of a portion overlapping the piezoelectric vibrating piece 140. Also, similarly to the opening portion 122, the opening portion 122a may have any size. Note that, although the opening portion 122a in FIG. 2B is fabricated with overlapping a part of the piezoelectric vibrating piece 140, the opening portion 122a may be fabricated with overlapping only the region S2 (that is, not overlapping the piezoelectric vibrating piece 140). Also, an opening portion 122b may be fabricated at a corner portion of the cavity 150 as shown by the dotted line in FIG. 2B.

Also, similarly to the opening portions 122a and 122b, if an opening portion is fabricated at a position overlapping, in plan view, a portion including the region S2, which is a region excluding the piezoelectric vibrating piece 140, similarly to the above-described opening portion 122, a large amount of ion beam is not irradiated to the piezoelectric vibrating piece 140 (excitation electrode 141a) during ion beam activation, and metals, which are sputtered from inside of the apparatus by ion beam irradiation, do not widely deposit on the excitation electrode 141a. Consequently, the piezoelectric device 100 having a vacuum hermetically sealed glass package can fabricated without changing the resonance frequency of the piezoelectric vibrating piece 140 even using the ion-beam activation bonding method.

### Fabricating Method of Piezoelectric Device 100

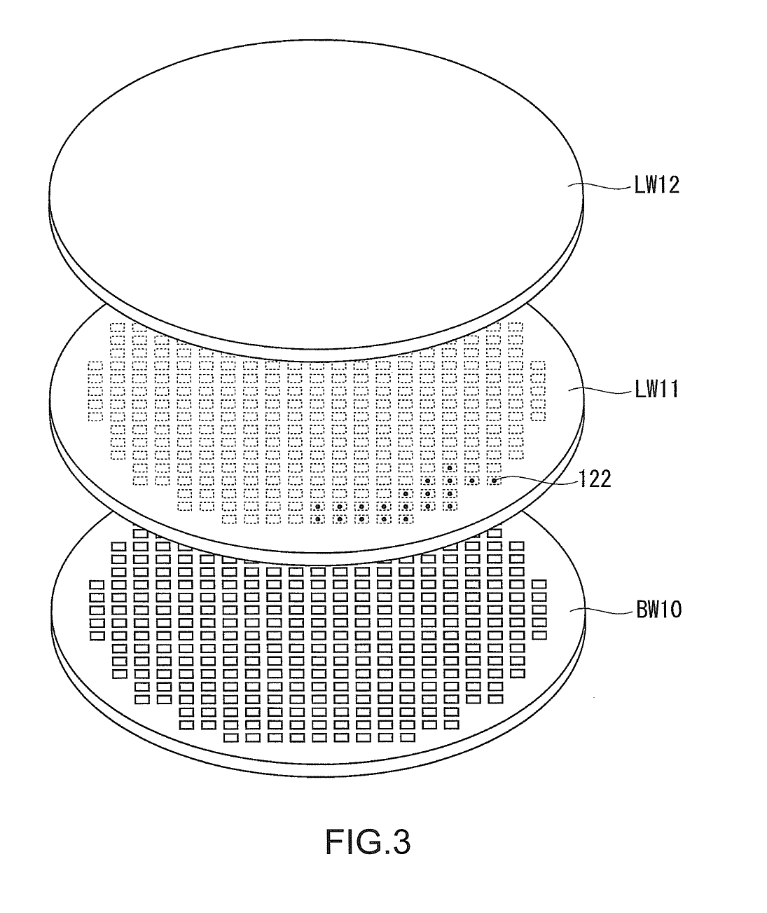

The following description describes a method for fabricating the piezoelectric device 100 with reference to FIG. 3. The piezoelectric device 100 is fabricated using a method referred to as wafer level packaging. In the fabrication of the piezoelectric vibrating piece 140, a multiple patterning is performed on a piezoelectric wafer from which individual pieces are cut out.

The piezoelectric vibrating piece 140 is formed into a shape having a desired frequency characteristic by a machining method. Then, the excitation electrodes 141a and 141b are respectively formed on the front surface and the back surface of the piezoelectric vibrating piece 140 by sputtering or evaporation using a metal mask stencil. Also, the piezoelectric vibrating piece 140 may be formed into a shape in which the peripheral portion is thinner than the center portion using convex processing. The excitation electrodes 141a and 141b have a two-layered structure including: chrome (Cr), titanium (Ti), nickel (Ni), nickel-chrome (NiCr) alloy, nickel-titanium (NiTi) alloy, or nickel-tungsten (NiW) alloy as a base layer for increasing adhesion with crystal, and a main electrode layer of gold (Au) or silver (Ag) which is formed on the base layer.

In the fabrication of the second lid 110, the first lid 120, and the base 130, a multiple patterning is respectively performed on a second lid wafer LW12, a first lid wafer LW11, and a base wafer BW10, from which individual pieces are cut out. The second lid wafer LW12, the first lid wafer LW11, and the base wafer BW10 are made of, for example, borosilicate glass. On the first lid wafer LW11, the depressed portion 121, which becomes the cavity 150, and the opening portion 122 are formed by sand-blasting or wet etching (forming process). Meanwhile, on the base wafer BW10, the through-holes for the through-hole interconnections 133a and 133b are formed by sand-blasting or wet etching.

On the base wafer BW10, the through-hole interconnections 133a and 133b are formed by, for example, filling the through-holes with copper plating or conductive paste, further the connecting electrodes 131a and 131b and the external electrodes 132a, 132b, 132c, and 132d are formed, the connecting electrodes 131a and 131b being used for the connection to the piezoelectric vibrating piece 140 placed on the base wafer BW10 via the conductive paste 142a and similar paste. The above-described connecting electrode 131a and similar electrode are formed by a method in which a film of gold (Au), nickel (Ni), or copper (Cu) is formed by sputter deposition on a base layer such as chrome (Cr), titanium (Ti), nickel (Ni), nickel-chrome (NiCr) alloy, nickel-titanium (NiTi) alloy, or nickel-tungsten (NiW) alloy, then an electrode is formed by electroless nickel plating on the film. Alternatively, the connecting electrode 131a and similar electrode are formed by a method in which a conductive paste including powder particles of silver or cooper is printed and is fired to be an electrode.

Next, the individual piezoelectric vibrating pieces 140 is placed on the base wafer BW10 by the conductive pastes 142a and 142b (placing process). The conductive pastes 142a and 142b electrically connects the excitation electrodes 141a and 141b of the piezoelectric vibrating piece 140 and the external electrode 132a and 132b.

Then, the resonance frequency of the individual piezoelectric vibrating pieces 140 on the base wafer BW10 is adjusted to the desired resonance frequency using a frequency adjusting apparatus (frequency adjustment process). In the frequency adjustment process, frequency adjustment is performed by monitoring the resonance frequency of the individual piezoelectric vibrating pieces 140 while sputter removing the excitation electrode 141a using an ion beam generator installed in the frequency adjusting apparatus until the desired resonance frequency is obtained with.

After the frequency adjustment is completed, the base wafer BW10 and the first lid wafer LW11 are bonded to each other (first bonding process). On the first lid wafer LW11, the depressed portions 121, which become the cavities 150, and the opening portions 122 are formed at positions where individual piezoelectric vibrating pieces 140 are housed. Bonding is required to be performed by a bonding method without changing the resonance frequency of the piezoelectric vibrating piece 140, in other words, without changing the mass of the piezoelectric vibrating piece 140. For this reason, bonding is performed by any one of the glass frit bonding method, the thermo-compression metal bonding method, the anodic bonding method, the plasma activation bonding method, which is other than the ion-beam activation bonding method.

For example, in the glass frit bonding method, bonding is performed as follows. A low melting point glass frit, which becomes the seal layer 160, is printed on the surface 120b, which becomes a bonding surface to the base 130, surrounding the depressed portion 121 of the first lid 120. Next, the first lid wafer LW11, on which the seal layer 160 of the glass frit is printed, is aligned and overlapped to the base wafer BW10. Then, the uniform pressure is applied to the wafers with heating the wafers near the softening temperature of the low melting point glass frit in nitrogen atmosphere. For the thermo-compression metal bonding method, metal that can be bonded by the thermo-compression metal bonding method, for example, Au, aluminum, or low melting point metal such as AuSn is used as the seal layer 160 instead of the low melting point glass frit.

While, in the anodic bonding method, alkali glass is used as at least one of the base wafer BW10 or the first lid wafer LW11, and the sealing surface (120b or 130a) of the other one is required to be coated with silicon (Si). In the anodic bonding method, bonding is performed by applying high temperature of 200° C. through 400° C. and high voltage of around 1 kV between the base wafer BW10 and the first lid wafer LW11. Strong bonding can be achieved by setting the alkali glass side as cathode, while setting the opposite side as anode. Note that, although the anodic bonding method is known for generating oxygen gas, the generated oxygen can be ejected through the opening portion 122, which is fabricated on the first lid wafer LW11, to the outside of the cavity 150. Accordingly, the characteristics of the piezoelectric vibrating piece 140 are not affected.

When the plasma activation bonding method is used for bonding the base wafer BW10 and the first lid wafer LW11, the respective bonding surfaces (120b and 130a) are exposed to oxygen plasma. Therefore, if the excitation electrode 141a on the piezoelectric vibrating piece 140 is not Au electrode, which is non-oxidation metal, the excitation electrode 141a is oxidized, which significantly changes the resonance frequency of the piezoelectric vibrating piece. Namely, the plasma activation bonding method cannot be used for the piezoelectric vibrating piece having an Ag electrode, the plasma activation bonding method is limited to the piezoelectric vibrating piece having the Au electrode.

Next, the second lid wafer LW12 is bonded to the first lid wafer LW11 using the ion-beam activation bonding method (second bonding process). The ion-beam activation bonding method is performed under a high vacuum atmosphere, then an air in the cavity 150, which is formed by bonding the base wafer BW10 and the first lid wafer LW11, is evacuated via the opening portion 122 formed on the first lid wafer LW11, which results in high vacuum condition in the cavity 150. Also, the piezoelectric vibrating piece 140 and the excitation electrode 141a, which is fabricated on the piezoelectric vibrating piece 140, are covered with the first lid 120. Accordingly, the irradiation of ion beam does not etch the excitation electrode 141a, and a large amount of metals, which is sputtered from inside of the apparatus by the irradiation of ion beam, do not deposit on the piezoelectric vibrating piece 140. Consequently, the cavity 150 can be sealed with high vacuum condition without changing the resonance frequency of the piezoelectric vibrating piece 140.

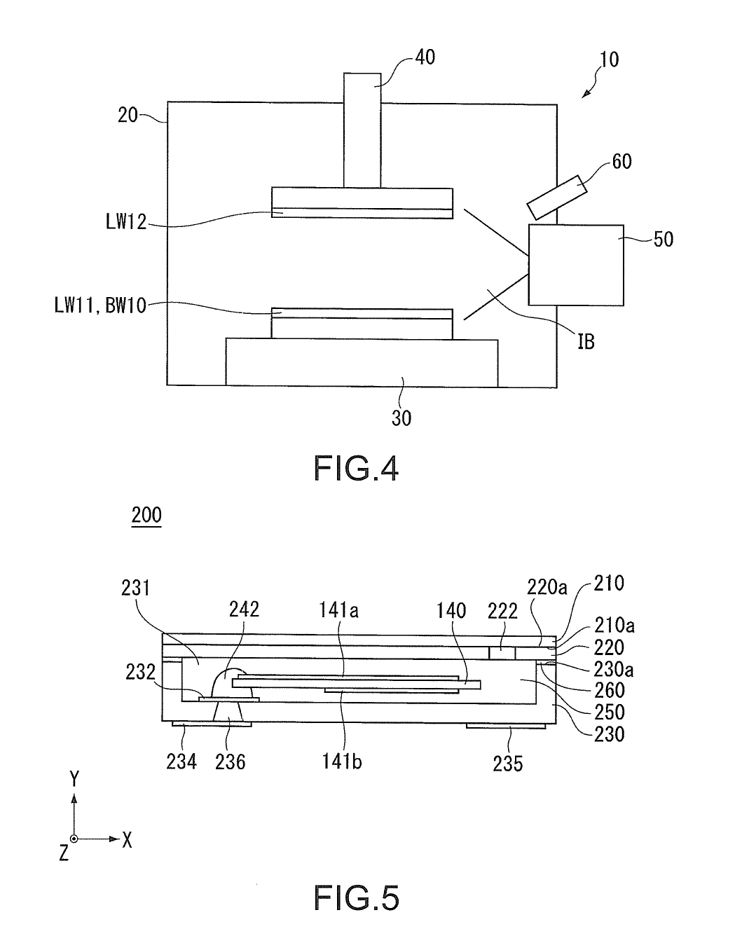

The ion-beam activation bonding method is performed using an ion beam activation bonding apparatus 10 illustrated in FIG. 4. As illustrated in FIG. 4, the ion beam activation bonding apparatus 10 includes a vacuum chamber 20, an alignment stage 30 having a wafer holder, a pressure applying mechanism 40 having a wafer holder, an ion source 50 fabricated for irradiating ion beam to a bonding surface, and a neutralized electron source 60. The vacuum chamber 20 is evacuated by a vacuum pump (not shown) (for example, turbomolecular pump), and a vacuum atmosphere is set in the vacuum chamber 20. Argon gas is provided to the ion source 50 and neutralized electron source 60 respectively via mass flow meters.

The second lid wafer LW12 is held on the wafer holder of the pressure applying mechanism 40 by, for example, an electro static chuck, while the bonded body of the base wafer BW10 and the first lid wafer LW11 is held on the wafer holder of the alignment stage 30. Note that, the second lid wafer LW12 is placed to face the first lid wafer LW11. Next, after the vacuum chamber 20 is evacuated to a predetermined pressure, argon beam (ion beam) IB is irradiated to both wafers from the ion source 50. Note that, the argon beam IB is neutralized by the neutralized electron source 60.

The surfaces of the first lid wafer LW11 and the second lid wafer LW12 are sputter etched to remove contamination by the argon beam IB. While the argon beam IB has a large divergence angle, the excitation electrode 141a is not etched since the piezoelectric vibrating piece 140 is covered with the first lid wafer LW11 as described above. In addition, the argon beam IB includes various kinds of metal components since each component of the ion beam activation bonding apparatus 10 is exposed to argon plasma to be sputtered. However, as described above, the metals hardly deposit on the piezoelectric vibrating piece 140 since the piezoelectric vibrating piece 140 is covered with the first lid wafer LW11.

Next, after the argon beam IB is irradiated for the predetermined time period, the first lid wafer LW11 (bonded body) and the second lid wafer LW12 are aligned to each other, then both wafers are bonded to each other with the condition of the predetermined pressure and press-contact time by the pressure applying mechanism 40. Afterwards, the bonded wafer is removed from the ion beam activation bonding apparatus 10, and is mounted to a dicing tape and is cut out by a dicing apparatus to complete individual piezoelectric devices 100 (dicing process).

As described above, the fabrication method of the piezoelectric device 100 allows fabricating, with high production yield, the piezoelectric devices 100 having a vacuum sealed glass package without changing the resonance frequency of the piezoelectric vibrating piece 140.

### Second Embodiment

The following description describes the second embodiment. In the following description, a component that is identical or equal to that of the first embodiment is indicated by the same reference numeral, and the description thereof is omitted or simplified. FIG. 5 illustrates a piezoelectric device 200 according to the second embodiment. In particular, FIG. 5 is a cross-sectional view taken along the line corresponding to the line IB-IB of FIGS. 1A and 1B. Similarly to the first embodiment, the piezoelectric device 200 includes the piezoelectric vibrating piece 140.

As illustrated in FIG. 5, the piezoelectric device 200 is a piezoelectric resonator that includes a second lid 210, a first lid 220, a base 230, and the piezoelectric vibrating piece 140. The base 230, on which the piezoelectric vibrating piece 140 is placed, is bonded to the first lid 220, for example, via a seal 260 made of a low melting point glass, further the first lid 220 is bonded to the second lid 210 by the ion-beam activation bonding method.

Similarly to the first embodiment, the second lid 210 is a plate-shaped member having a rectangular shape. The second lid 210 includes a bonding surface 210a, which is bonded to the first lid 220, having a sufficient smoothness appropriate for bonding by the ion-beam activation bonding method (typically, the average roughness Ra is around 1 mm).

Similarly to the second lid 210, the first lid 220 is a plate-shaped member, which includes an opening portion 222 passing through the first lid 220 in the Y direction. The first lid 220 includes a bonding surface 220a, which is bonded to the second lid 210, having a sufficient smoothness appropriate for bonding by the ion-beam activation bonding method (typically, the average roughness Ra is around 1 nm). On the other hand, a surface of the first lid 220, which is bonded to the base 230, is not required to have a smoothness required for bonding by the ion-beam activation bonding method. However, it may have a similar smoothness.

Similarly to the opening portion 122 of the first embodiment, the opening portion 222 serves as a through-hole for evacuating space (cavity) 250 around the piezoelectric vibrating piece 140 when the second lid 210 is bonded to the first lid 220 after the first lid 220 is bonded to the base 230. Also, the opening portion 222 is fabricated at a position that can reduce the influence to the piezoelectric vibrating piece 140 by ion beams when the second lid 210 is bonded to the first lid 220.

The base 230 is a plate-shaped member having a rectangular shape in plan view, and has a depressed portion 231 on the front surface (+Y-side surface) as illustrated in FIG. 5. The base 230 has a bonding surface 230a, which is bonded to the first lid 220, surrounding the depressed portion 231. Bonding the first lid 220 and the base 230 forms a cavity 250 (housing space) which houses the piezoelectric vibrating piece 140.

A connecting electrode 232 is fabricated in the depressed portion 231 of the base 230, and an external electrode 234 and a dummy electrode 235 are fabricated on the back surface of the base 230. A through-hole interconnection 236, which passes through the base 230 in the Y direction, is fabricated between the connecting electrode 232 and the external electrode 234, and the through-hole interconnection 236 electrically connects the connecting electrode 232 and the external electrode 234. Note that, the connecting electrode 232, the external electrode 234, and the through-hole interconnection 236 are approximately similar to those of the piezoelectric device 100 according to the first embodiment. The excitation electrodes 141a and 141b of the piezoelectric vibrating piece 140 are electrically connected to the external electrodes 234 via conductive pastes 242, and can activate the piezoelectric vibrating piece 140.

A bonding manner between the base 230 and the first lid 220, and a bonding manner between the second lid 210 and the bonded body of the base 230 and the first lid 220 are similar to those of the first embodiment. Also, a fabrication method of the piezoelectric device 200 is approximately similar to that of the first embodiment.

Similar to the opening portion 122 illustrated in FIG. 2A, the opening portion 222 is fabricated at a position overlapping, in plan view, a portion including the region S1, which is a region excluding the excitation electrode 141a on the piezoelectric vibrating piece 140. Also, similarly to the opening portions 122a and 122b illustrated in FIG. 2B, the opening portion 222 may be fabricated at a position overlapping, in plan view, a portion including the region S2, which is a region excluding the excitation electrode 141a. Further, the opening portion 222 may be fabricated at a position along the bonding portion to the base 230. Note that, similarly to the opening portion 122 of the first embodiment, the opening portion 222 may have any size, and any number of the opening portion 222 may be fabricated.

Thus, in the piezoelectric device 200, similarly to the first embodiment, when the second lid 210 is bonded to the first lid 220 using the ion-beam activation bonding method, air in the cavity 250 can be ejected through the opening portion 222 fabricated on the first lid 220, which results in high vacuum condition in the cavity 250. In addition, the piezoelectric vibrating piece 140 and the excitation electrode 141a, which is fabricated on the piezoelectric vibrating piece 140 are covered with the first lid 220, accordingly the irradiation of ion beam does not etch the excitation electrode 141a, and metals, which are sputtered from inside of the apparatus by the irradiation of ion beam, do not deposit on the piezoelectric vibrating piece 140. Consequently, the cavity 150 can be sealed with high vacuum condition without changing the resonance frequency of the piezoelectric vibrating piece 140.

### Configuration of Piezoelectric Device 300 According to Third Embodiment

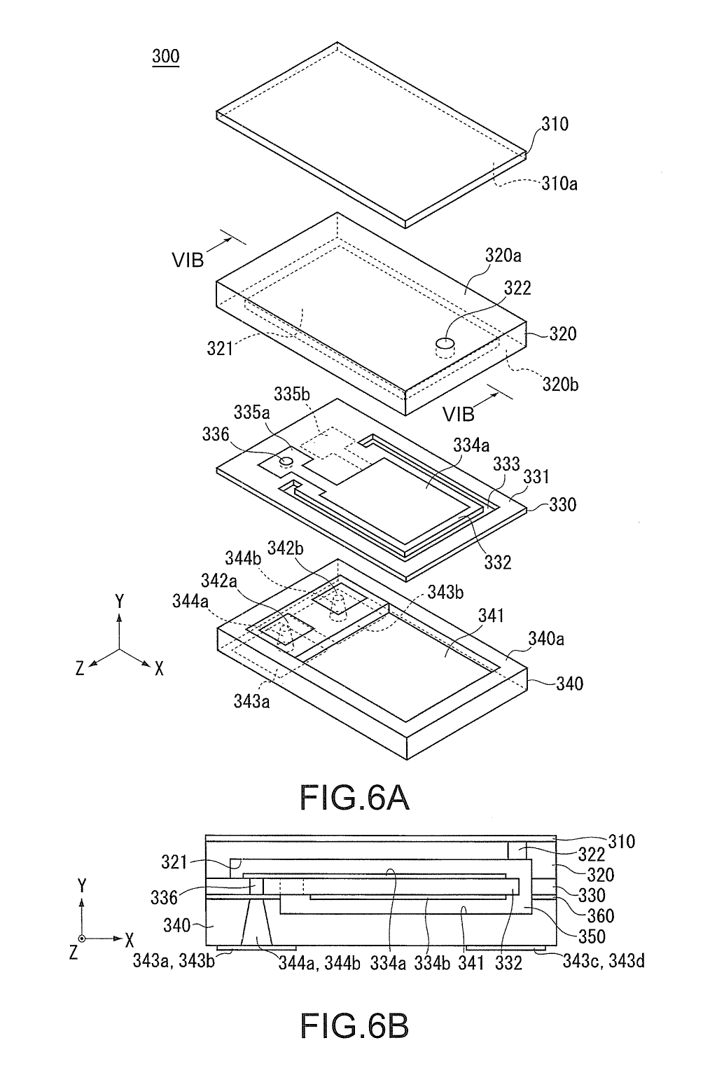

The following description describes a piezoelectric device 300 according to the third embodiment with reference to FIGS. 6A and 6B. As illustrated in FIG. 6A, the piezoelectric device 300 is a piezoelectric resonator that includes a second lid 310, a first lid 320, a base 340, and a piezoelectric vibrating piece 330 that has a framing portion 331. The first lid 320 is bonded to the +Y-side surface of the piezoelectric vibrating piece 330, and the base 340 is bonded to the −Y-side surface of the piezoelectric vibrating piece 330 so as to sandwich the piezoelectric vibrating piece 330. Further the second lid 310 is bonded to the +Y-side surface of the first lid 320. Similarly to the first and the second embodiment, the second lid 310, the first lid 320, and the base 340 are made of borosilicate glass.

As illustrated in FIG. 6A, the second lid 310 is a plate-shaped member having a rectangular shape. The second lid 310 includes a bonding surface 310a, which is bonded to the first lid 320, having a sufficient smoothness appropriate for bonding by the ion-beam activation bonding method (typically, the average roughness Ra is around 1 nm).

The first lid 320 is a plate-shaped member having a rectangular shape in plan view, and has a depressed portion 321 on the back surface (−Y-side surface) as illustrated in FIG. 6A. An opening portion 322 is disposed at a portion of the depressed portion 321. The first lid 320 includes a bonding surface 320a, which is bonded to the second lid 310, having a sufficient smoothness appropriate for bonding by the ion-beam activation bonding method (typically, the average roughness Ra is around 1 nm). On the other hand, a bonding surface 320b of the first lid 320 surrounding depressed portion 321, in which the bonding surface 320b is bonded to the framing portion 331 of the piezoelectric vibrating piece 330, is not required to have a smoothness required for bonding by the ion-beam activation bonding method. However, the bonding surface 320b may have a similar smoothness.

The opening portion 322 serves as a through-hole for evacuating space (cavity) 350 around a vibrating portion 332 formed on the piezoelectric vibrating piece 330 when the second lid 310 is bonded to the first lid 320 after the first lid 320, the piezoelectric vibrating piece 330, and the base 340 are bonded. Also, the opening portion 322 is fabricated at a position that can reduce the influence to the vibrating portion 332 by ion beams. For example, the opening portion 322 is fabricated at a position right above a through-hole 333, which is between the framing portion 331 and the vibrating portion 332, when the second lid 310 is bonded to the first lid 320.

As illustrated in FIG. 6A, the piezoelectric vibrating piece 330 has a structure in which the through-hole 333 separates the framing portion 331 and the vibrating portion 332. Excitation electrodes 334a and 334b, which excite the vibrating portion 332, are respectively fabricated on the front surface and back surface of the vibrating portion 332 (see FIG. 6B). Also, an extraction electrode 335a and extraction electrodes 335b and 335c are respectively disposed on the front surface and back surface of the vibrating portion 332. The extraction electrode 335a on the front surface (+Y-side surface) is electrically connected to the extraction electrode 335c on the back surface (−Y-side surface) via a through-hole interconnection 336 Note that, the extraction electrode 335c is fabricated right below the extraction electrode 335a, therefore the extraction electrode 335c is omitted in FIGS. 6A and 6B.

The piezoelectric vibrating pieces 330 are formed in a lot, for example, on an AT-cut crystal wafer using photolithography process and etching process. The vibrating portion 332 of the piezoelectric vibrating piece 330 is formed with a rectangular-shape, and has the same thickness in the Y-axis direction as that of the framing portion 331. Alternatively, the thickness of the vibrating portion 332 may be thinner than that of the framing portion 331. Also, the vibrating portion 332 may be formed with a mesa shape in which the central portion is thicker than the peripheral portion.

The excitation electrodes 334a and 334b and the extraction electrode 335a, 335b, and 335c are conductive metal layers including: chrome (Cr), titanium (Ti), nickel (Ni), nickel-chrome (NiCr) alloy, nickel-titanium (NiTi) alloy, or nickel-tungsten (NiW) alloy as a base layer for increasing adhesion with a crystal, and a main electrode layer of gold (Au) or silver (Ag) is formed on the base layer. In addition, the through-hole interconnection 336 may be formed by filling a through-hole with a conductive material. Alternatively, the through-hole interconnection 336 may be formed by tapering the through-hole to form a conductive metal layer on the side surface of the through-hole for making an electrical connection between the front and back surfaces during the film formation of the excitation electrode 334a and similar electrode, or the extraction electrode 335a and similar electrode.

The base 340 is formed with a rectangular-shape, and has a depressed portion 341, which is fabricated on the front surface (+Y-side surface), and a bonding surface 340a, which surrounds the depressed portion 341 as illustrated in FIG. 6A. The bonding surface 340a faces a back surface (−Y-side surface) of the framing portion 331 of the piezoelectric vibrating piece 330.

As illustrated in FIG. 6A, connecting electrodes 342a and 342b are fabricated in a region at the −X-side on the front surface of the base 340, while external electrodes 343a and 343b are fabricated in a region at the −X-side on the back surface of the base 340. Also, through-hole interconnections 344a and 344b, which pass through the base 340 in the Y direction, are fabricated on the base 340, and the through-hole interconnections 344a and 344b electrically connect the connecting electrode 342a (342b) and the external electrode 343a (343b). Note that, as illustrated in FIG. 6B, dummy electrodes 343c and 343d are fabricated in a region at the +X-side on the back surface of the base 340. In FIG. 6A, the dummy electrodes 343c and 343d are omitted.

The connecting electrode 342a and similar electrodes, the external electrode 343a and similar electrodes, and the through-hole interconnection 344a and similar electrodes are made of metal similar to that of the first and second embodiments. In addition, a connection between the connecting electrode 342a and similar electrodes, and the external electrode 343a and similar electrodes is not limited to the through-hole interconnection 344a or similar wirings. For example, at the corners or the sides of the base 340, cutouts (castellation) may be formed, then the connecting electrode 342a and similar electrodes, and the external electrodes 343a and similar electrodes may be connected to each other by electrodes formed at the cutouts.

As illustrated in FIG. 6B, the base 340 is bonded to the back surface (−Y-side surface) of the piezoelectric vibrating piece 330 via a seal layer 360, which is fabricated between the bonding surface 340a and the back surface of the flaming portion 331. The seal layer 360 is made of, for example, low melting point glass or Au, aluminum, and low melting point metal such as AuSn, a bonding material used for the low melting point glass bonding method or the thermo-compression metal bonding method, or silicon (Si) used for the anodic bonding method. For bonding the base 340 to the piezoelectric vibrating piece 330, a bonding method may be used, which does not require the seal layer 360, such as the ion-beam activation bonding method, or the plasma activation bonding method. Bonding the piezoelectric vibrating piece 330 to the base 340 electrically connects the extraction electrodes 335c and 335b to the connecting electrodes 342a and 342b, respectively.

Note that, after the piezoelectric vibrating piece 330 is bonded to the base 340, the piezoelectric vibrating piece 330 is bonded to the first lid 320, then the first lid 320 is bonded to the second lid 310 in the same manner as the above described bonding between the base 130 and the first lid 120 and the bonding between the first lid 120 and the second lid 110 of the first embodiment.

Similarly to the opening portion 122 illustrated in FIG. 2A, the opening portion 322 is fabricated at a position overlapping, in plan view, a portion including the region S1, which is a region excluding the excitation electrode 334a of the vibrating portion 332 of the piezoelectric vibrating piece 330. Also, similarly to the opening portions 122a and 122b illustrated in FIG. 2B, the opening portion 322 may be fabricated at a position overlapping, in plan view, a portion including the region S2, which is a region excluding the vibrating portion 332 (that is, through-hole 333). Further, the opening portion 322 may be fabricated at a position along the framing portion 331 (the bonding portion to the base 230). Note that, similarly to the opening portion 122 of the first embodiment, the opening portion 322 may have any size, and any number of the opening portion 322 may be fabricated.

Thus, according to the piezoelectric device 300, the piezoelectric devices 300 having a vacuum hermetically sealed glass package can be provided without changing the resonance frequency of the vibrating portion 332 of the piezoelectric vibrating piece 330.

### Fabrication Method of Piezoelectric Device 300

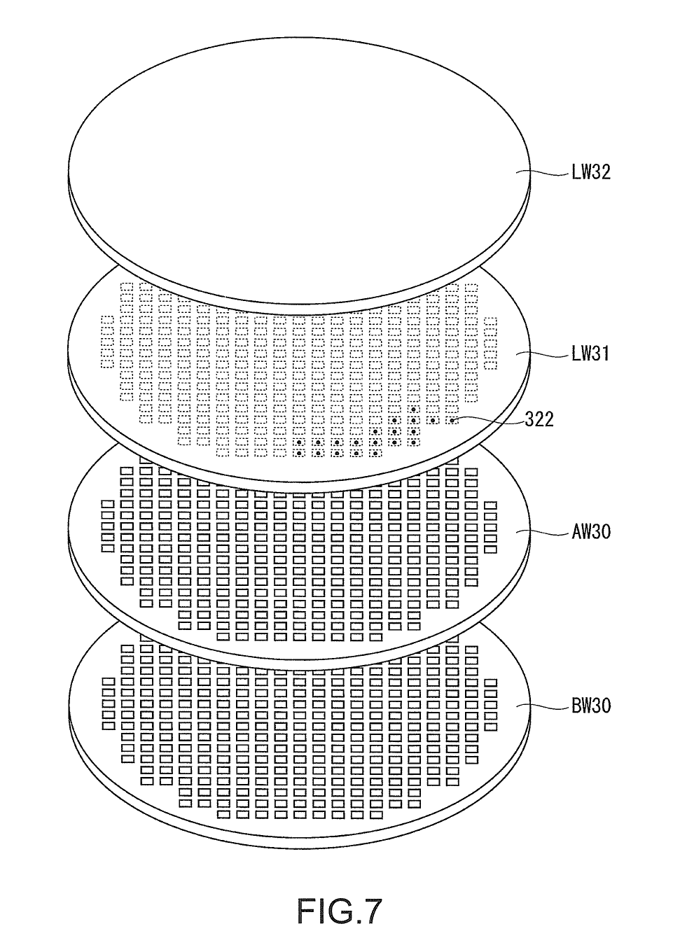

The following description describes a method for fabricating the piezoelectric device 300 with reference to FIG. 7. The piezoelectric device 300 is fabricated using a method referred to as wafer level packaging. The piezoelectric vibrating piece 330 is made from, for example, an AT-cut crystal wafer as a piezoelectric wafer AW30. The piezoelectric vibrating piece 330 is designed to have a desired frequency characteristic on the piezoelectric wafer AW30, then the vibrating portion 332 and similar portion are formed using the photolithography process and the etching process. Note that, the vibrating portion 332 may be formed into a shape in which the peripheral portion is thinner than the center portion using convex processing. On the piezoelectric wafer AW30, patterns illustrated in FIG. 6A are formed in a lot with being arranged. After the vibrating portion 332 and similar portion are formed, the excitation electrodes 334a and 334b and the extraction electrode 335a, 335b, and 335c are formed on the front surface and the back surface of the vibrating portion 332 by sputtering or evaporation using a metal mask stencil.

The excitation electrodes 334a and 334b and the extraction electrode 335a, 335b, and 335c are formed by forming a layer including: chrome (Cr), titanium (Ti), nickel (Ni), nickel-chrome (NiCr) alloy, nickel-titanium (NiTi) alloy, or nickel-tungsten (NiW) alloy as a base layer for increasing adhesion with a crystal, and a main electrode layer of gold (Au) or silver (Ag) is formed on the base layer.

The second lid 310, the first lid 320, and the base 340 having the above-described structure are respectively formed on a second lid wafer LW32, a first lid wafer LW31, and a base wafer BW30 using the photolithography process and the etching process. The second lid wafer LW32, the first lid wafer LW31, and the base wafer BW30 are made of, for example, borosilicate glass. On the first lid wafer LW31, the depressed portion 321, which becomes a cavity 350, and the opening portion 322 are formed by sand-blasting or wet etching.

On the base wafer BW30, through-holes for the through-hole interconnections 344a and 344b are formed by sand-blasting or wet etching. The through-hole interconnections 344a and 344b are formed by, for example, filling the through-holes with copper plating or a conductive paste. Further, the connecting electrodes 342a and 342b, the external electrodes 343a and 343b, and the dummy electrodes 343c and 343d are respectively formed.

The external electrodes 343a and 343b and the dummy electrodes 343c and 343d are formed by a method in which gold (Au), Nickel (Ni), or copper (Cu) is formed by sputter deposition on a base layer such as chrome (Cr), titanium (Ti), nickel (Ni), nickel-chrome (NiCr) alloy, nickel-titanium (NiTi) alloy, or nickel-tungsten (NiW) alloy, on which an electrode is formed by electroless nickel plating. Alternatively, the connecting electrode 343a and similar electrode may be formed by a method in which a conductive paste including powder particles of silver or copper is printed and is fired to be an electrode.

Next, the piezoelectric wafer AW30 is bonded to the base wafer BW30 (on the +Y-side surface) (base bonding process). The base wafer BW30 and the piezoelectric wafer AW30 are bonded to each other after they are aligned with an alignment mark. Bonding the piezoelectric wafer AW30 to the base wafer BW30 respectively electrically connects the excitation electrodes 334a and 334b of the piezoelectric vibrating piece 330 to the external electrodes 343a and 343b.

In the base bonding process, the extraction electrodes 335b and 335c fabricated on the back surface of the piezoelectric vibrating piece 330 should be respectively electrically connected to the connecting electrodes 342b and 342a fabricated on the front surface of the base 340 at the time when the back surface of the framing portion 331 of the piezoelectric vibrating piece 330 is bonded to the bonding surface 340a of the base 340. Thus, both sides can be electrically connected to each other by patterning the seal layer 360, which is made of the same metal as the connecting electrodes 342b and 342a on the front surface of the base 340, on the back surface (−Y-side surface) of the framing portion 331 of the piezoelectric vibrating piece 330 and on the bonding surface 340a facing thereof. That is, the connecting electrodes 342b and 342a and the metal seal layer 360 are formed in the same way as the excitation electrodes 334a and 334b of the piezoelectric vibrating piece 330 and the extraction electrodes 335a, 335b, and 335c. For example, if the back surface (−Y-side surface) of the framing portion 331 of the piezoelectric vibrating piece 330, the excitation electrode 334b and the extraction electrodes 335b and 335c of the piezoelectric vibrating piece 330, the outer periphery portion (including the bonding surface 340a) of the front surface (+Y-side surface) of the base 340, and the connecting electrodes 342a and 342b have a structure in which Cr, Ti, Ni, NiCr, NiTi, NiW or similar material is formed as a base layer on which Au is patterned, an electrical connection and a sealing bonding are achieved at the same time by thermo-compression metal bonding method.

Then, in the individual piezoelectric vibrating pieces 330 bonded to the base wafer BW30, the resonance frequency of the vibrating portion 332 is adjusted to the desired resonance frequency using a frequency adjusting apparatus (frequency adjustment process). In the frequency adjustment process, frequency adjustment is performed by monitoring the resonance frequency of the individual vibrating portions 332 during sputter-removal from the excitation electrode 334a using an ion beam generator installed in the frequency adjusting apparatus, until the desired resonance frequency is obtained with.

After that, the first lid wafer LW31 is bonded to the piezoelectric wafer AW30 (to the +Y-side surface) whose frequency have been adjusted (first bonding process). The first lid wafer LW31 is bonded to the piezoelectric wafer AW30 after the position of the vibrating portion 332 is aligned to the position of the depressed portion 321 fabricated on the first lid 320 using the alignment mark of the piezoelectric wafer AW30 and the first lid wafer LW31. Here, the bonding is performed by a bonding method without changing the resonance frequency of the vibrating portion 332, in other words, without changing the mass of the vibrating portion 332.

For example, in the glass frit bonding method, bonding is performed as follows. A low melting point glass frit, which becomes the seal layer, is printed on the bonding surface 320b of the first lid 320. Next, the first lid wafer LW31 is aligned and overlapped to the piezoelectric wafer AW30. Then, the uniform stress is applied to the wafers with heating the wafers near the softening temperature of the low melting point glass frit in nitrogen atmosphere. In the thermo-compression metal bonding method, a metal that can be bonded by the metal pressure welding method, for example, gold, aluminum, or low melting point metal such as AuSn is used as a seal layer instead of the low melting point glass frit.

While, in the anodic bonding method, alkali glass is used as the first lid wafer LW31, the surface (+Y-side surface) of the framing portion 331 of the piezoelectric wafer AW30 is required to be coated with silicon (Si). In the anodic bonding method, bonding is performed by applying high temperature of 200 through 400° C. and high voltage of around 1 kV between the piezoelectric wafer AW30 and the first lid wafer LW31. Strong bonding can be achieved by setting the first lid wafer LW31 side as cathode, and setting the piezoelectric wafer AW30 side as anode. Note that, while the anodic bonding method is known for generating oxygen gas, the generated oxygen can be ejected through the opening portion 322, which is fabricated on the first lid wafer LW31, to the outside of the cavity 350, accordingly the characteristics of the vibrating portion 332 is not affected.

When the plasma activation bonding method is used for bonding the piezoelectric wafer AW30 and the first lid wafer LW31, the respective bonding surfaces (the front surface of the framing portion 331, bonding surface 320b) are exposed to oxygen plasma, therefore, if the excitation electrode 334a on the vibrating portion 332 is not Au electrode, which is non-oxidation metal, the excitation electrode 334a is oxidized, which significantly changes the resonance frequency of the vibrating portion 332. Namely, the plasma activation bonding method cannot used for the piezoelectric vibrating piece having an Ag electrode, the plasma activation bonding method is limited to the piezoelectric vibrating piece having the Au electrode.

Next, the second lid wafer LW32 is bonded to the first lid wafer LW31 using the ion-beam activation bonding method (second bonding process). The ion-beam activation bonding method is performed under high vacuum, then an air in the cavity 350, which is formed by bonding the piezoelectric wafer AW30 and the first lid wafer LW31, is ejected through the opening portion 322 formed on the first lid wafer LW31, which results in high vacuum condition in the cavity 350. Also, the vibrating portion 332 and the excitation electrode 334a, which are fabricated on the vibrating portion 332 are covered with the first lid 320. Accordingly the irradiation of ion beam does not etch the vibrating portion 332 and the excitation electrode 334a, and metals, which are sputtered from inside of the apparatus by the irradiation of ion beam, do not deposit on the vibrating portion 332. Consequently, the cavity 350 can be sealed with high vacuum condition without changing the resonance frequency of the vibrating portion 332.

Note that, similarly to the first embodiment, the ion-beam activation bonding method is performed using the ion beam activation bonding apparatus 10 illustrated in FIG. 4.

Then, the bonded wafer, to which the second lid wafer LW32 has been bonded, is mounted to a dicing tape and is cut out by a dicing apparatus to complete individual piezoelectric devices 300 (dicing process).

As described above, similarly to the above-described fabrication method of the piezoelectric device 100, the fabrication method of the piezoelectric device 300 allows to fabricate, with high production yield, the piezoelectric devices 300 having a vacuum hermetically sealed glass package without changing the resonance frequency of the vibrating portion 332.

Above all, although the embodiments are described, this disclosure is not limited to the above-described explanations, and various kinds of modifications can be made without departing the scope of the disclosure. For example, a tuning-fork type piezoelectric vibrating piece (quartz crystal piece) can be used instead of the piezoelectric vibrating piece 140 or similar vibrating piece. In addition, the piezoelectric vibrating piece 140 or similar piezoelectric vibrating piece is not limited to a quartz crystal piece, but any other piezoelectric materials such as lithium tantalate and lithium niobate can be used. Also, a Micro Electro Mechanical Systems (MEMS) device or any other devices, in which silicon wafers are used, can be used instead of the piezoelectric vibrating piece 140 or similar piezoelectric vibrating piece. In addition, a piezoelectric device is not limited to be a piezoelectric resonator (crystal unit), but can be an oscillator. If the oscillator is used, the oscillator includes an Integrated Circuit (IC), and is electrically connected to the piezoelectric vibrating piece 140 or similar vibrating piece. Further an AT-cut crystal wafer may be used as the first lid wafers LW11 and LW31, the second lid wafers LW12 and LW32, and the base wafers BW10 and BW30.

In the disclosure, the opening portion may be fabricated at a position along a bonding portion of the base and the first lid.

In the disclosure, a piezoelectric device may include a piezoelectric vibrating piece, a base, a first lid, and a second lid. The piezoelectric vibrating piece includes a vibrating portion, a framing portion surrounding the vibrating portion, an anchor portion connecting the vibrating portion and the framing portion, and an electrode fabricated on at least the vibrating portion. The base is bonded to a back surface of the framing portion. The first lid is bonded to a front surface of the framing portion. The first lid includes an opening portion that opens an inside of the framing portion. The second lid is bonded to a front surface of the first lid so as to cover the opening portion. The opening portion is fabricated at a position overlapping a portion including a region of the vibrating portion excluding the electrode, or a portion including a region excluding the vibrating portion, in plan view. The opening portion may be fabricated at a position along the framing portion.

The second lid may have a shape that covers a whole front surface of the first lid. A bonding between the first lid and the second lid may be performed by ion-beam activation bonding method, and another bonding may be performed by bonding method other than the ion-beam activation bonding method.

In the disclosure, a method for fabricating a piezoelectric device including a piezoelectric vibrating piece includes: a placing process for placing the piezoelectric vibrating piece on a base; a forming process for forming an opening portion on a first lid; a first bonding process for bonding the first lid to the base; and a second bonding process for bonding a second lid to the first lid so as to cover the opening portion using an ion-beam activation bonding method.

In the disclosure, a method for fabricating a piezoelectric device including a piezoelectric vibrating piece with a vibrating portion and a framing portion surrounding the vibrating portion includes: a base bonding process for bonding a base to a back surface of the framing portion; a forming process for forming an opening portion on a first lid; a first bonding process for bonding the first lid to a front surface of the framing portion; and a second bonding process for bonding a second lid to the first lid so as to cover the opening portion using an ion-beam activation bonding method.

According to this disclosure, the ion-beam activation bonding method is performed with covering the piezoelectric vibrating piece (vibrating portion) with the first lid, which allows to reduce etching of the electrodes fabricated on the piezoelectric vibrating piece (vibrating portion), and deposition of metals on the electrodes of the piezoelectric vibrating piece (vibrating portion). This allows reducing the resonance frequency variation of the piezoelectric device to prevent the production of inferior goods, then improves the production yield.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric device, comprising:
a piezoelectric vibrating piece that includes an electrode;
a base that holds the piezoelectric vibrating piece;
a first lid bonded to the base, the first lid housing the piezoelectric vibrating piece in a cavity, the first lid having an opening portion that opens the cavity; and
a second lid bonded to a front surface of the first lid so as to cover the opening portion, wherein
the opening portion is fabricated at a position overlapping a portion including a region of the piezoelectric vibrating piece excluding the electrode, or a portion including a region excluding the piezoelectric vibrating piece, in plan view.

2. The piezoelectric device according to claim 1, wherein
the opening portion is fabricated at a position along a bonding portion of the base and the first lid.

3. The piezoelectric device according to claim 1, wherein
the second lid has a shape that covers a whole front surface of the first lid.

4. The piezoelectric device according to claim 1, wherein
a bonding between the first lid and the second lid is performed by an ion-beam activation bonding method, and
another bonding is performed by a bonding method other than the ion-beam activation bonding method.

5. A piezoelectric device, comprising:
a piezoelectric vibrating piece, including: a vibrating portion, a framing portion surrounding the vibrating portion, an anchor portion connecting the vibrating portion and the framing portion, and an electrode fabricated on at least the vibrating portion;
a base, being bonded to a back surface of the framing portion to hold the piezoelectric vibrating piece;
a first lid, being bonded to a front surface of the framing portion, the first lid including an opening portion that opens an inside of the framing portion; and
the opening portion is fabricated at a position overlapping a portion including a region of the vibrating portion excluding the electrode, or a portion including a region excluding the vibrating portion, in plan view.

6. The piezoelectric device according to claim 5, wherein
the opening portion is fabricated at a position along the framing portion.

7. The piezoelectric device according to claim 5, wherein
the second lid has a shape that covers a whole front surface of the first lid.

8. The piezoelectric device according to claim 5, wherein
a bonding between the first lid and the second lid is performed by an ion-beam activation bonding method, and
another bonding is performed by a bonding method other than the ion-beam activation bonding method.

9. A method for fabricating the piezoelectric device according to claim 1, comprising:
a placing process for placing the piezoelectric vibrating piece on a base;
a forming process for forming an opening portion on a first lid;
a first bonding process for bonding the first lid to the base; and
a second bonding process for bonding a second lid to the first lid, so as to cover the opening portion using an ion-beam activation bonding method.

10. A method for fabricating the piezoelectric device according to claim 5, comprising:
a preparing process for preparing the piezoelectric vibrating piece including the vibrating portion, the framing portion surrounding the vibrating portion, the anchor portion connecting the vibrating portion and the framing portion, and the electrode disposed on at least the vibrating portion;
a base bonding process for bonding the base to the back surface of the framing portion; and
the first bonding process includes a bonding process for bonding the first lid to the front surface of the framing portion.
